(19) United States
(12) Patent Application Publication
(10) Pub. No.: US 2024/0349479 A1
(43) Pub. Date: Oct. 17, 2024

(54) SIMPLIFIED MANUFACTURE OF SEMICONDUCTOR MEMORY DEVICE

(71) Applicant: YANGTZE MEMORY TECHNOLOGIES CO., LTD., Wuhan (CN)

(72) Inventors: Zhaoyun TANG, Wuhan (CN); Ya WANG, Wuhan (CN); Wenxiang XU, Wuhan (CN); Dongmen SONG, Wuhan (CN); WenYu HUA, Wuhan (CN); FanDong LIU, Wuhan (CN); Zhi ZHANG, Wuhan (CN)

(21) Appl. No.: 18/352,907

(22) Filed: Jul. 14, 2023

(30) Foreign Application Priority Data
Apr. 14, 2023 (CN) 2023104089282

(51) Int. Cl. H10B 12/00

(52) U.S. Cl. CPC H10B 12/05; H10B 12/315

(57) ABSTRACT

Examples include forming first trenches extending along a first direction on a first side of a semiconductor layer, and forming an insulation layer within the first trenches; forming second trenches extending along a second direction on the first side, the depths of the second trenches less than depths of the first trenches, the first and second directions intersecting; forming a first gate insulation layer and first gate conductive layer sequentially on inner walls of the second trenches; removing part of the semiconductor layer, part of the insulation layer and part of the first gate insulation layer from a second side of the semiconductor layer facing away from the first side, to expose the first gate conductive layer; and removing a part of the first gate conductive layer from the second side, to divide the first gate conductive layer into first gates located on opposite sidewalls of the second trenches respectively.

### CROSS-REFERENCE TO RELATED APPLICATIONS

The present application claims priority to Chinese Patent Application No. 2023104089282, which was filed Apr. 14, 2023, is titled “Manufacturing Method of Semiconductor Device, Semiconductor Device, and Memory System,” and is hereby incorporated herein by reference in its entirety.

### TECHNICAL FIELD

The present application relates to the technical field of semiconductors, and more particularly to a manufacturing method of a semiconductor device, a semiconductor device and a memory system.

### BACKGROUND

A dynamic random access memory (DRAM) generally employs one capacitor and one transistor to constitute one memory cell, and the memory cells are arranged in a two-dimensional array. Such arrays may take the form of a vertical gate transistor (VGT) array, in which an extending direction of a transistor channel is perpendicular to the surface of a substrate; a source and a drain are respectively formed at two ends of the channel in the extending direction; and a gate insulation layer and a gate are sequentially formed on at least one side of the channel.

### SUMMARY

The present application provides a manufacturing method of a semiconductor device, a semiconductor device and a memory system which can at least partially solve the above-mentioned problems existing in the related arts or other problems in the field.

Some implementations of the present application provide a manufacturing method of a semiconductor device. The manufacturing method comprises: forming first trenches extending along a first direction on a first side of a semiconductor layer, and forming an insulation layer within the first trenches; forming second trenches extending along a second direction on the first side, depths of the second trenches being less than depths of the first trenches, wherein the first direction intersects the second direction; forming a first gate insulation layer and a first gate conductive layer sequentially on inner walls of the second trenches; removing part of the semiconductor layer, part of the insulation layer and part of the first gate insulation layer from a second side of the semiconductor layer facing away from the first side, to expose the first gate conductive layer; and removing a part of the first gate conductive layer from the second side, to divide the first gate conductive layer into first gates located on opposite sidewalls of the second trenches respectively.

In some implementations, the manufacturing method further comprises: forming third trenches extending along the second direction on the first side, the third trenches and the second trenches being arranged alternately in the first direction; and forming a second gate insulation layer within the third trenches.

In some implementations, forming a second gate insulation layer within the third trenches comprises: forming a second gate insulation layer on inner walls of the third trenches; and forming a conductive layer within space surrounded by the second gate insulation layer.

In some implementations, the manufacturing method further comprises: removing a part of the conductive layer from the second side, such that an exposed surface of the conductive layer is substantially flush with an exposed surface of the first gate conductive layer.

In some implementations, in a process of removing a part of the first gate conductive layer, a part of the conductive layer is removed in the same process, such that an exposed surface of the conductive layer is substantially flush with an exposed surface of the first gate conductive layer.

In some implementations, the material of the conductive layer includes titanium nitride.

In some implementations, the manufacturing method further comprises: removing a part of the first gate conductive layer and a part of the conductive layer from the first side, such that an exposed surface of the first gate conductive layer is substantially flush with an exposed surface of the conductive layer; and filling an insulating material within space of the second trenches and the third trenches.

In some implementations, the first gate conductive layer comprises a gate blocking layer and a gate metal layer, and wherein forming the first gate insulation layer and the first gate conductive layer sequentially on the inner walls of the second trenches comprises: forming the first gate insulation layer, the gate blocking layer and the gate metal layer sequentially on the inner walls of the second trenches.

In some implementations, the material of the gate blocking layer includes titanium nitride, and the material of the gate metal layer includes tungsten.

In some implementations, after removing a part of the first gate conductive layer from the second side to divide the first gate conductive layer into the first gates located on the opposite sidewalls of the second trenches respectively, the manufacturing method further comprises: forming an insulation structure covering the semiconductor layer on the second side.

Some other implementations of the present application provide a semiconductor device comprising: a plurality of semiconductor pillars arranged in an array along a first direction and a second direction, first ends of the plurality of semiconductor pillars arranged along the first direction being connected with each other; a first gate insulation layer located on first sidewalls of the semiconductor pillars and extending along the second direction; and first gates located on a surface of the first gate insulation layer and extending along the second direction, wherein surfaces of a plurality of the first gates close to the first ends are substantially flush, the first direction, the second direction and a third direction intersect each other, and the third direction is an extending direction of each of the semiconductor pillars.

In some implementations, the thicknesses of the first gates in the first direction are consistent along the third direction.

In some implementations, the cross-section shapes of the first gates on a plane perpendicular to the second direction are rectangular.

In some implementations, the semiconductor device further comprises: a second gate insulation layer located on second sidewalls of the semiconductor pillars and extending along the second direction, the first sidewalls and the second sidewalls being opposite sidewalls in the first direction; and a conductive layer located on a surface of the second gate insulation layer and extending along the second direction.

In some implementations, the second gate insulation layer, the conductive layer and the second gate insulation layer are sequentially disposed along the first direction between adjacent ones of the semiconductor pillars in the first direction.

In some implementations, the material of the conductive layer includes titanium nitride.

In some implementations, the first gates comprise a gate blocking layer and a gate metal layer, and the gate blocking layer is located between the surface of the first gate insulation layer and the gate metal layer.

In some implementations, the material of the gate blocking layer includes titanium nitride, and the material of the gate metal layer includes tungsten.

In some implementations, the sizes of the first gates in the third direction are the same as the size of the conductive layer in the third direction.

Some further implementations of the present application provide a memory system which comprises: at least one semiconductor device as mentioned in any implementation above; and a memory controller coupled to the semiconductor device and configured to control the semiconductor device.

According to at least one implementation of the present application, based on the manufacturing method of the semiconductor device, the semiconductor device and the memory system provided by the present application, the first gate insulation layer and the first gate conductive layer are directly formed on the inner walls of the second trenches, and part of the semiconductor layer, part of the first gate insulation layer and a part of the first gate conductive layer are removed from the second side of the semiconductor layer, and then, the first gate conductive layer is divided into the first gates located on the opposite sidewalls of the second trenches respectively. As compared with some related arts, performing filling and multiple back-etchings on the second trenches from the first side may be omitted, thereby being favorable to save the process cost and optimize the process window. The first gates located on the opposite sidewalls of the second trenches are formed on the second side, thereby being favorable to reduce process difficulty and improve the adaptability of technical evolution.

In addition, since the surfaces of the plurality of first gates close to the first ends are substantially flush, the structure consistency of the first gates in the semiconductor device can be improved, thereby being favorable to improve the influence on the performance of the semiconductor device due to structure differences.

### BRIEF DESCRIPTION OF THE DRAWINGS

Other features, purposes and advantages of the present application will become more apparent by reading the detailed description of non-limiting implementations made by reference to the following drawings. In the drawings:

FIG. 1 is a flow diagram of a method for manufacturing a semiconductor device according to example implementations of the present application;

FIGS. 2A to 8C are schematic diagrams of intermediate structures of a semiconductor device formed during a manufacturing process, in accordance with example implementations of the present application;

FIGS. 9A to 9C are schematic diagrams of a semiconductor device in accordance with example implementations of the present application; and

FIG. 10 is a schematic diagram of a memory cell in accordance with example implementations of the present application.

### DETAILED DESCRIPTION

Various aspects of the present application are now described in more detail with reference to the drawings. These detailed descriptions are only descriptions of example implementations of the present application, and they are not intended to limit the scope of the present application in any manner. Like reference numbers denote like elements throughout the specification. The expression “and/or” includes any and all combinations of one or more of the listed associated items.

In the specification, expressions such as “first,” “second,” “third,” and the like are only used to distinguish one feature from another feature, instead of representing any limitation to the features, particularly instead of representing any sequential order. Thus, without departing from the teaching of the present application, a first trench discussed in the present application may be also called a second trench, or vice versa.

For ease of illustration, the thicknesses, sizes and shapes of components have been slightly adjusted in the drawings. The drawings are merely illustrative and are not drawn to scale precisely. As used herein, terms, “approximately”, “about”, and the like, are used to represent approximation, instead of representing a degree, and are intended to describe inherent deviations in measured values or calculated values as recognized by those of ordinary skill in the art.

Expressions such as “comprise”, “comprising”, “have”, “include”, and/or “including”, etc., are open-ended expressions, rather than close-ended expressions in the specification. They represent the existence of the stated features, elements and/or components, but the existence of one or more other features, elements, components and/or combinations thereof is not precluded. Moreover, expressions such as “at least one of . . . ,” appearing before a list of listed features, modifies the whole list of features, rather than an individual element therein. Furthermore, “may” is used to represent “one or more implementations of the present application” when describing the implementations of the present application.

Unless otherwise defined, all phrases (including engineering terms and technical terms) as used herein have the same meanings as those generally understood by those of ordinary skill in the art to which the present application pertains. Terms as defined in common dictionaries should be interpreted as having a meaning that is consistent with their meaning in the context of the related art, and should not be interpreted in an idealized or overly formal sense unless otherwise stated expressly in the present application.

Implementations and features in the implementations of the present application may be mutually combined in the case of no conflicts. In addition, unless otherwise defined expressly or conflicting with the context, specific operations included in a method as set forth in the present application are not necessarily limited to the described order, but may be carried out in any order or in parallel.

Furthermore, “connected” or “joined,” when used in the present application, may represent direct contact or indirect contact between respective components, unless otherwise expressly defined or derived from the context.

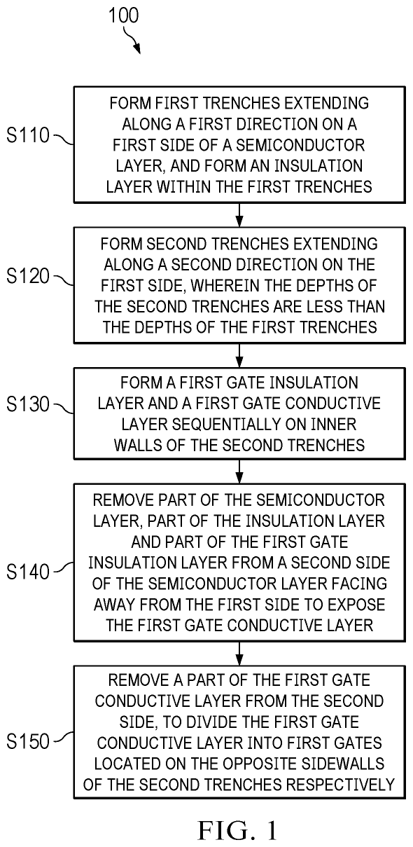

Some implementations of the present application provide a manufacturing method of a semiconductor device. FIG. 1 is a flow diagram of a manufacturing method 100 of a semiconductor device according to example implementations of the present application. As shown in FIG. 1, the manufacturing method 100 of the semiconductor device (hereinafter referred to as the manufacturing method 100) comprises operations S110 to S150.

Operation S110 includes forming first trenches extending along a first direction on a first side of a semiconductor layer, and forming an insulation layer within the first trenches.

Operation S120 includes forming second trenches extending along a second direction on the first side, wherein the depths of the second trenches are less than the depths of the first trenches.

Operation S130 includes forming a first gate insulation layer and a first gate conductive layer sequentially on inner walls of the second trenches.

Operation S140 includes removing part of the semiconductor layer, part of the insulation layer and part of the first gate insulation layer from a second side of the semiconductor layer facing away from the first side to expose the first gate conductive layer.

Operation S150 includes removing a part of the first gate conductive layer from the second side, to divide the first gate conductive layer into first gates located on the opposite sidewalls of the second trenches respectively.

According to the manufacturing method of the semiconductor device provided by this implementation, the first gate insulation layer and the first gate conductive layer are directly formed on the inner walls of the second trenches. Part of the semiconductor layer, part of the first gate insulation layer and a part of the first gate conductive layer are removed from the second side of the semiconductor layer. The first gate conductive layer is divided into the first gates located on the opposite sidewalls of the second trenches respectively. As compared with some related arts, the operation of performing filling and multiple back-etchings on the second trenches from the first side can be omitted, thereby being favorable to mitigate process costs and optimize the process window. In addition, the first gates located on the opposite sidewalls of the second trenches are formed on the second side, thereby being favorable to reduce process difficulty and improve the adaptability of technical evolution.

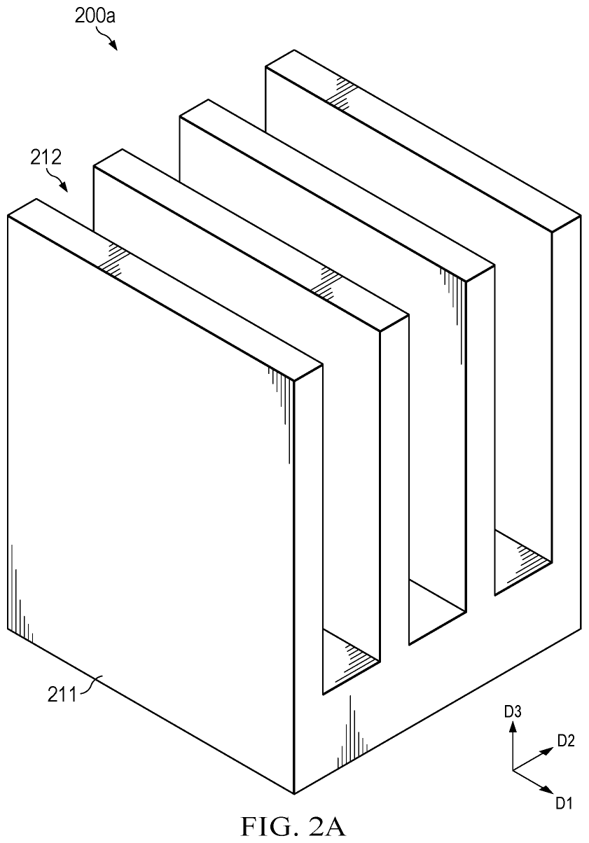

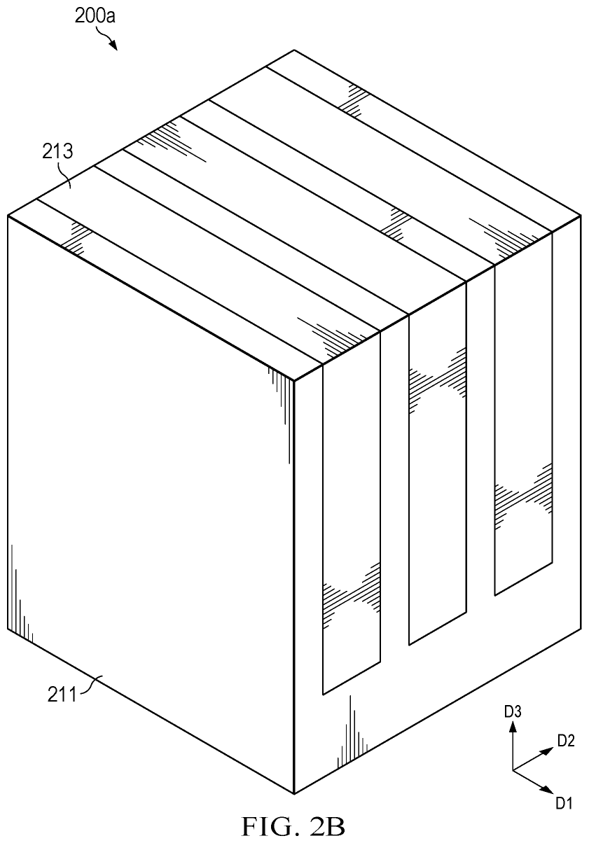

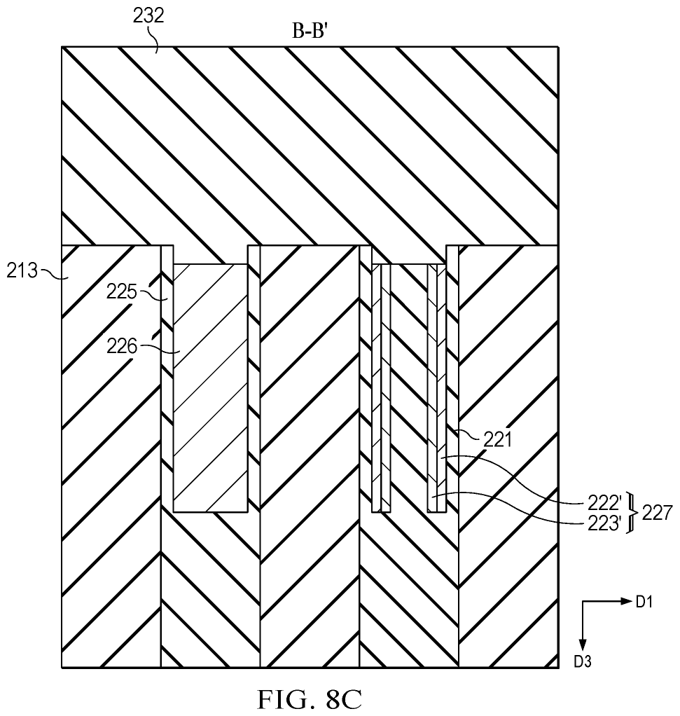

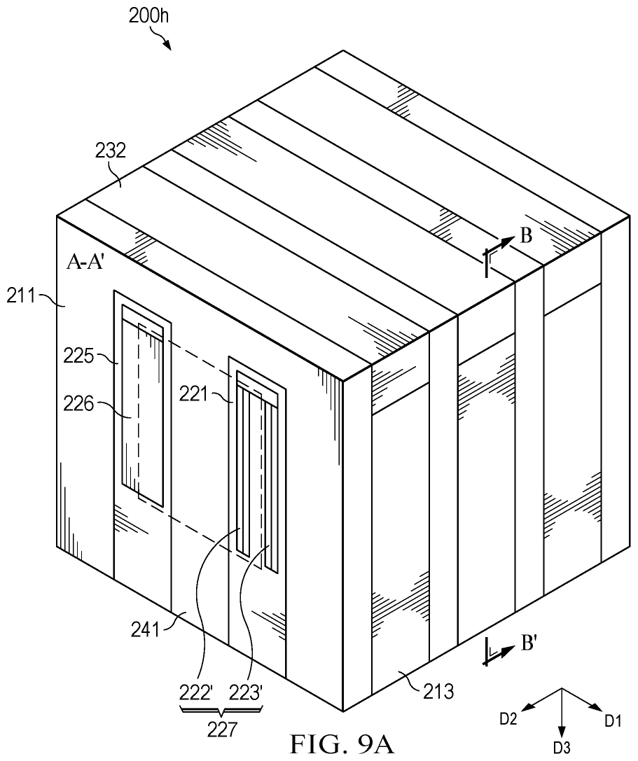

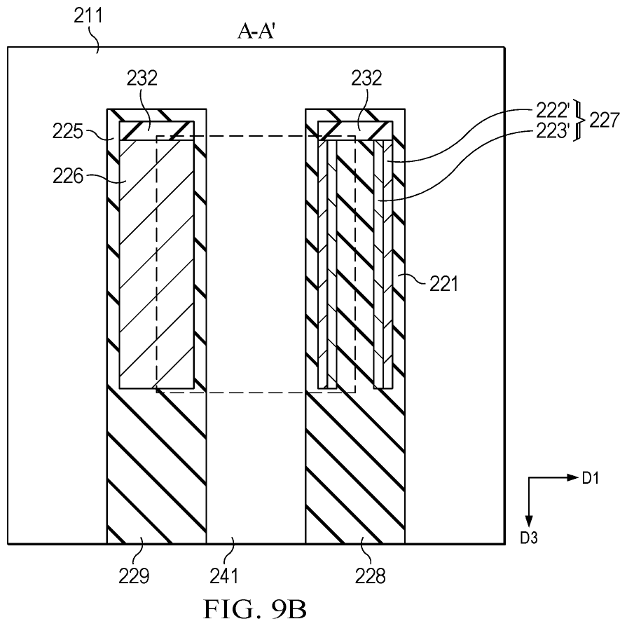

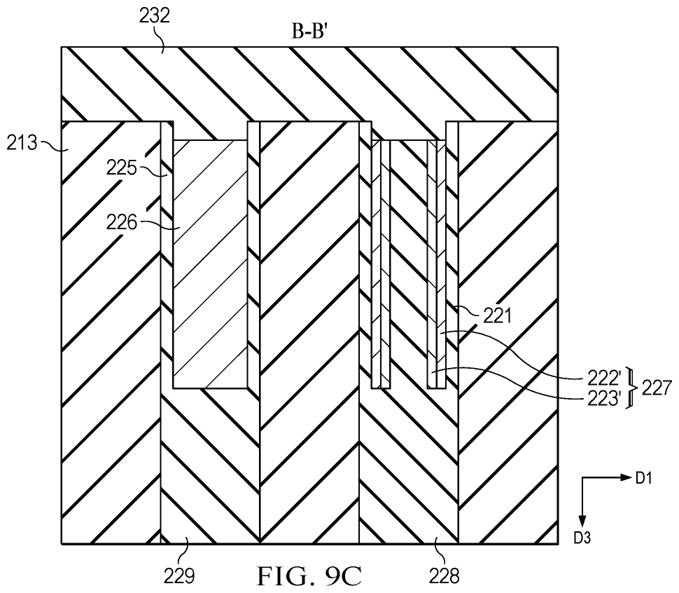

FIGS. 2A to 8C are schematic diagrams of intermediate structures of a semiconductor device of example implementations of the present application in a manufacturing process. FIGS. 9A to 9C are schematic diagrams of a semiconductor device of example implementations of the present application. For example, the intermediate structures of the semiconductor device as shown in FIGS. 2A to 8C and the semiconductor device as shown in FIGS. 9A to 9C may be formed according to the manufacturing method 100 as shown in FIG. 1. The above-mentioned operations S110 and S150 are described below in conjunction with FIGS. 2A to 9C.

Operation S110 includes forming first trenches extending along a first direction on a first side of a semiconductor layer, and forming an insulation layer within the first trenches.

FIGS. 2A and 2B show an intermediate structure 200a of the semiconductor device after performing operation S110. As shown in FIG. 2A, a semiconductor layer 211 may be, for example, a substrate. The material of the semiconductor layer 211 may comprise silicon (e.g., monocrystalline silicon c-Si), silicon germanium (SiGe), gallium arsenide (GaAs), germanium (Ge), silicon on insulator (SOI), or any other suitable semiconductor materials. For example, the semiconductor layer 211 may be a silicon substrate.

In operation S110, as shown in FIG. 2A, the semiconductor layer 211 may be etched from the first side of the semiconductor layer 211 with an etching (e.g., dry etching or wet etching) process to form the first trenches 212 extending along the first direction D1. Openings of the first trenches 212 face the first side. Further, as shown in FIG. 2B, an insulation layer 213 may be formed within the first trenches 212 with any suitable thin film deposition process, such as physical vapor deposition (PVD), chemical vapor deposition (CVD), atomic layer deposition (ALD), etc. In some implementations, the material of the insulation layer 213 may include, but not be limited to, silicon 3498-00400 7 oxide, silicon nitride, silicon oxynitride, or any other suitable insulating materials. For example, the material of the insulation layer 213 is silicon oxide.

In some implementations, as shown in FIG. 2A, multiple first trenches 212 may be formed in the same etching process, and multiple portions of the insulation layer 213 are formed in the same thin film deposition process, as shown in FIG. 2B. For example, the spacing distances between adjacent portions of the insulation layer 213 in a second direction D2 are the same.

Operation S120 includes forming second trenches extending along a second direction on the first side, wherein the depths of the second trenches are less than the depths of the first trenches.

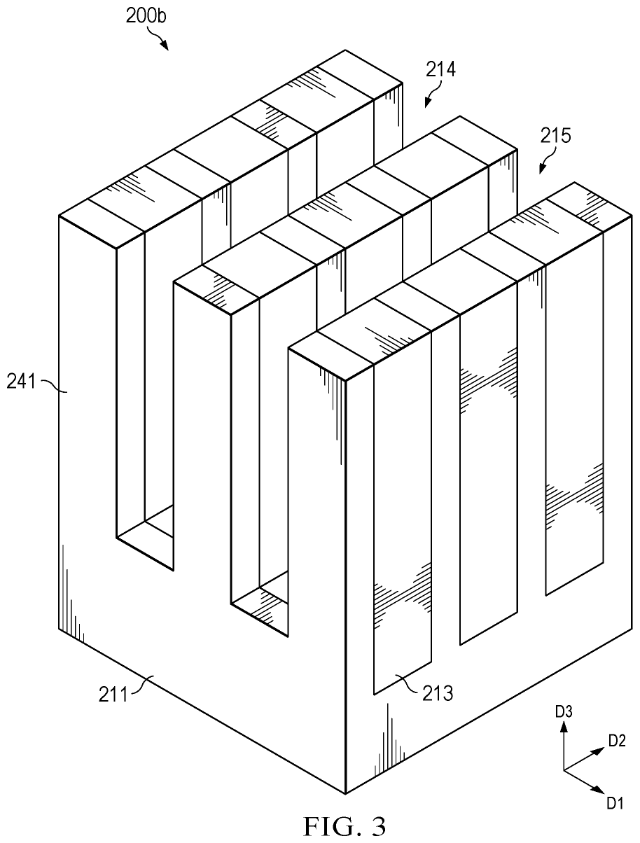

FIG. 3 shows an intermediate structure 200b of the semiconductor device after performing operation S120. As shown in FIG. 3, the semiconductor layer 211 and the insulation layer 213 may be etched from the first side of the semiconductor layer 211 with an etching (e.g., dry etching or wet etching) process to form the second trenches 214 extending along the second direction D2. Openings of the second trenches 214 face the first side. The first direction DI intersects the second direction D2. For example, the first direction DI is perpendicular to the second direction D2.

The depths of the second trenches 214 are less than the depths of the first trenches 212 (referring to FIG. 2A). In other words, the second trenches 214 do not penetrate through the insulation layer 213 completely, and bottom faces of the second trenches 214 are constituted by surfaces of the semiconductor layer 211 and the insulation layer 213 arranged in the second direction D2.

In some implementations, the semiconductor layer 211 and the insulation layer 213 may be etched from the first side of the semiconductor layer 211 with an etching (e.g., dry etching or wet etching) process to form third trenches 215 extending along the second direction D2. For example, the depths of the third trenches 215 are less than the depths of the first trenches 212. For another example, the depths of the third trenches 215 are equal to the depths of the second trenches 214. The second trenches 214 and the third trenches 215 are arranged alternately in the first direction D1.

In some implementations, multiple second trenches 214 and multiple third trenches 215 may be formed in the same etching process. For example, the adjacent second trenches 214 and third trenches 215 have the same or different spacing distances in the first direction D1, to which the present application does not impose limitations.

In the intermediate structure 200b, the second trenches 214 and/or the third trenches 215 divide the semiconductor layer 211 into a plurality of semiconductor pillars 241. The plurality of semiconductor pillars 241 are arranged in an array in the first direction D1 and the second direction D2, each of the semiconductor pillars 241 extending in a third direction D3, and first ends of several semiconductor pillars 241 arranged in the first direction D1 far away from the first side are connected with each other through the semiconductor layer 211.

Operation S130 includes forming a first gate insulation layer and a first gate conductive layer sequentially on inner walls of the second trenches.

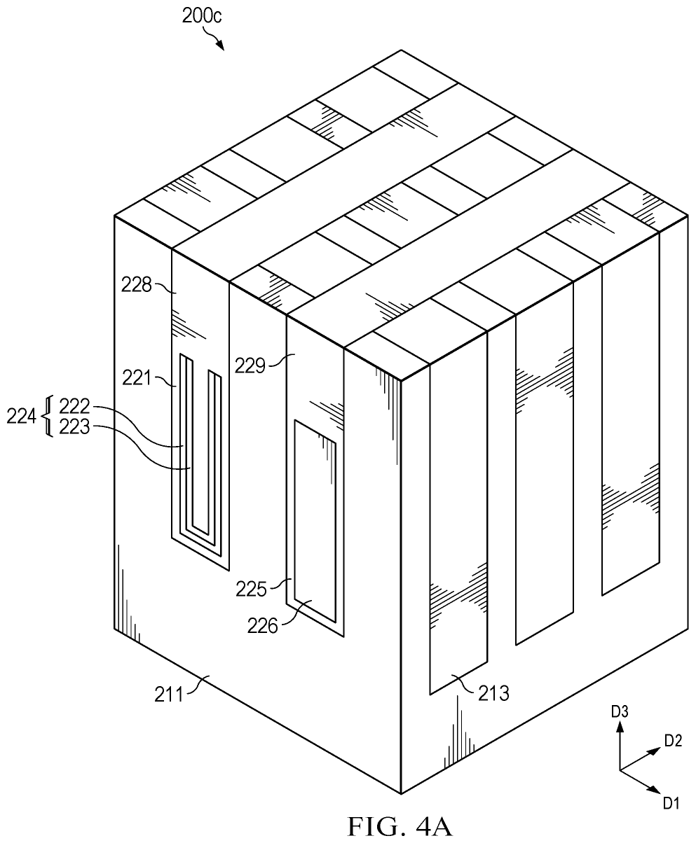

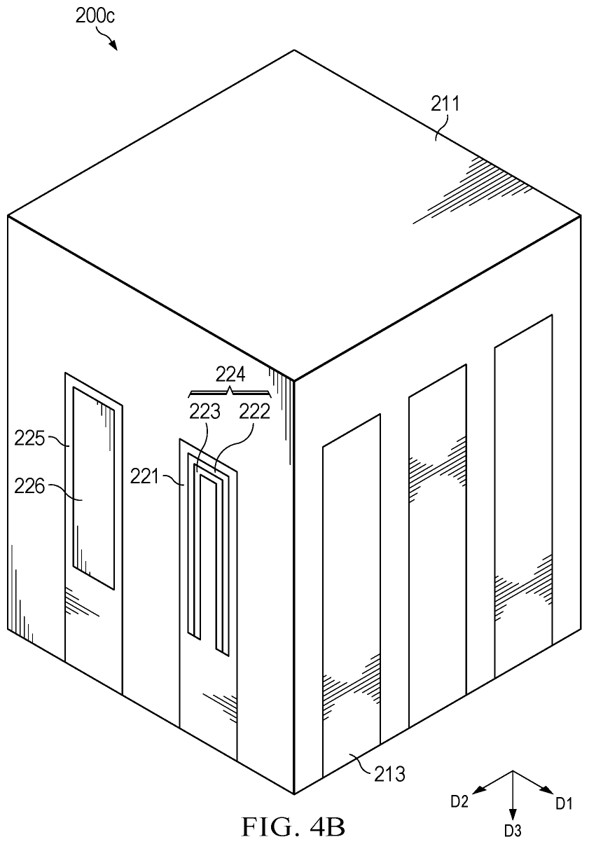

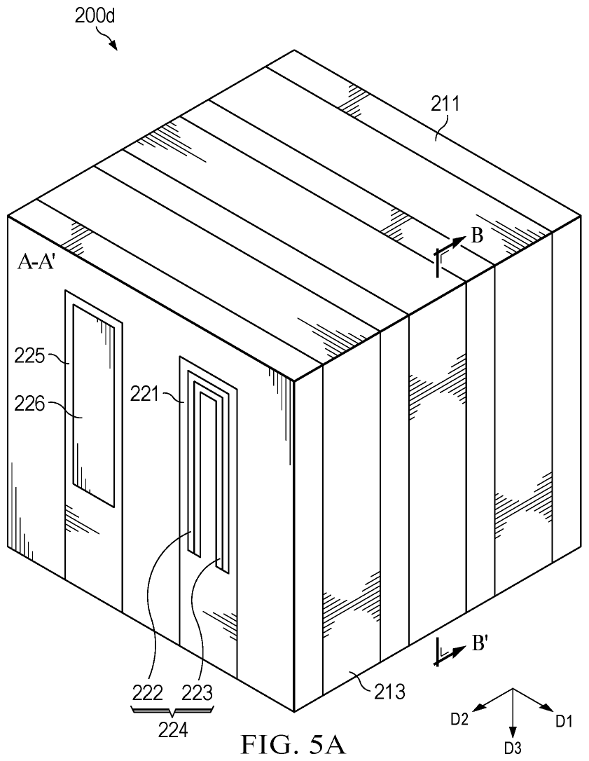

FIG. 4A shows an intermediate structure 200c of the semiconductor device after performing operation S130. FIG. 4B is a schematic diagram of the intermediate structure 200c as shown in FIG. 4A after being flipped 180°.

As shown in FIGS. 3 and 4A, the first gate insulation layer 221, gate blocking layer 222 and gate metal layer 223 may be sequentially formed on the inner walls (i.e., bottoms and sidewalls) of the second trenches 214 with any suitable thin film deposition process, such as PVD, CVD, ALD, etc. In some implementations, the material of the first gate insulation layer 221 includes any suitable insulating material, such as silicon oxide, silicon nitride, silicon oxynitride, etc. For example, the material of the gate insulation layer is silicon oxide. In some implementations, the material of the gate blocking layer 222 includes, but is not limited to, titanium, titanium nitride, tantalum, tantalum nitride, etc., and the material of the gate metal layer 223 includes, but is not limited to, tungsten, copper. aluminum, etc. For example, the material of the gate blocking layer 222 is titanium nitride, and the material of a gate conductive layer 224 is tungsten. The gate blocking layer 222 is used to block diffusion of metal materials and also used to improve mutual attachment between the first gate insulation layer 221 and the gate metal layer 223.

The gate blocking layer 222 and the gate metal layer 223 may be referred to as a first gate conductive layer 224. In some implementations, the gate blocking layer 222 may be omitted, and the gate metal layer 223 serves as the first gate conductive layer 224, to which the present application does not impose limitations.

In some implementations, part of the first gate conductive layer 224 on the sidewalls of the second trenches 214 (referring to FIG. 3) may be removed from the first side of the semiconductor layer 211 using an etching (e.g., dry etching or wet etching) process, and an insulating material is filled within space surrounded by the first gate conductive layer 224 and within space of the second trenches 214 (referring to FIG. 3) close to the openings to form first insulating material layer 228. For example, the insulating material includes silicon oxide. When the material of the first gate insulation layer 221 is silicon oxide, there is no obvious boundary between the first insulating material layer 228 and the first gate insulation layer 221.

In some implementations, as shown in FIGS. 3 and 4A, any suitable thin film deposition process, such as PVD, CVD, ALD, etc., may be employed to form second gate insulation layer 225 on inner walls (i.e., bottoms and sidewalls) of the third trenches 215, and form conductive layer 226 within space surrounded by the second gate insulation layer 225. In some examples, the material of the first gate insulation layer 221 includes any suitable insulating material, such as silicon oxide, silicon nitride, silicon oxynitride, etc., and the material of the conductive layer 226 includes any suitable conductive material, such as tungsten, copper, aluminum, titanium nitride, tantalum nitride, doped polysilicon, etc. For example, the material of the second gate insulation layer 225 is silicon oxide, and the material of the conductive layer 226 is titanium nitride. Optionally, a part of the conductive layer 226 may be removed from the first side of the semiconductor layer 211 using an etching (e.g., a dry etching or wet etching) process, and an insulating material may be used to fill space of the third trench 215 (referring to FIG. 3) to close the opening in the conductive layer 226 to form a second insulating material layer 229. For example, the insulating material includes silicon oxide. When the material of the second gate insulation layer 225 is silicon oxide, there is no obvious boundary between the second insulating material layer 229 and the second gate insulation layer 225. The conductive layer 226 may serve as back gates. For example, the interference between adjacent word lines may be prevented by applying a reference voltage (e.g., a ground voltage) to the back gates.

The present application does not limit the order of the operations of removing part of the first gate conductive layer 224 and removing part of the conductive layer 226. The etching process may be controlled to make the exposed surface of the conductive layer 226 after removing part of the conductive layer 226 substantially flush with the exposed surface of the first gate conductive layer 224 after removing part of the first gate conductive layer 224, such that the parts of the first gate conductive layer 224 and the conductive layer 226 close to the first side in the third direction D3 are relatively symmetrical, thereby being favorable to improve the control performance. Due to the limitation of the process, the error range of the exposed surface of the conductive layer 226 and the exposed surface of the first gate conductive layer 224 relative to the same reference plane may be between −10% and 10%.

In some implementations, the second gate insulation layer (not shown) may be completely filled within the third trenches 215 (referring to FIG. 3) with any suitable thin film deposition process, such as PVD. CVD, ALD, etc. Optionally, air gaps may be formed in the second gate insulation layer by controlling the thin film deposition process. The insulation performance may be improved by forming the air gaps in the second gate insulation layer, thereby preventing the interference between the adjacent word lines.

In some implementations, filling structures (not shown) that are completely the same as those inside the second trenches 214 may be formed within the third trenches 215. Thus, the conductive layer may be located on the sidewalls of the third trenches 215 (referring to FIG. 3). For example, the conductive layer is divided into two second gates located on the opposite sidewalls of the third trenches in a subsequent process. As compared with the conductive layer completely filled within the space surrounded by the second gate insulation layer, the two second gates can control the transistors on two sides thereof separately, thereby being favorable to improve the control flexibility of the back gates.

After performing operation S130, as shown in FIG. 4B, subsequent operations may be performed on the intermediate structure 200c by flipping the intermediate structure 200c 180°.

Operation S140 includes removing part of the semiconductor layer, part of the insulation layer and part of the first gate insulation layer from a second side of the semiconductor layer facing away from the first side to expose the first gate conductive layer.

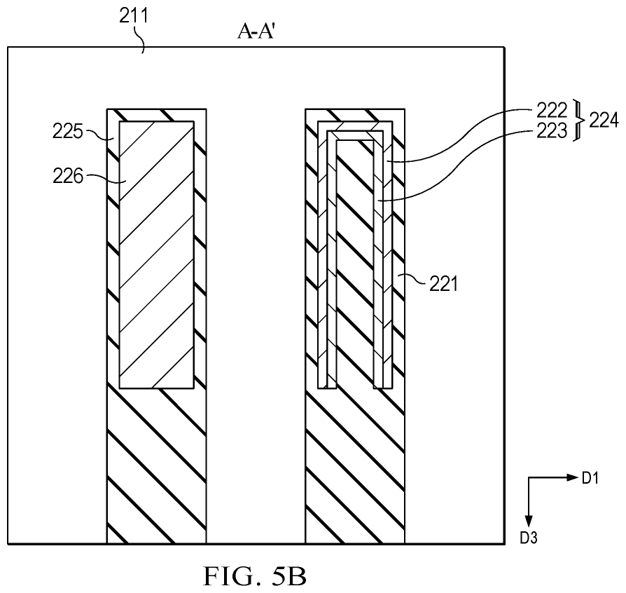

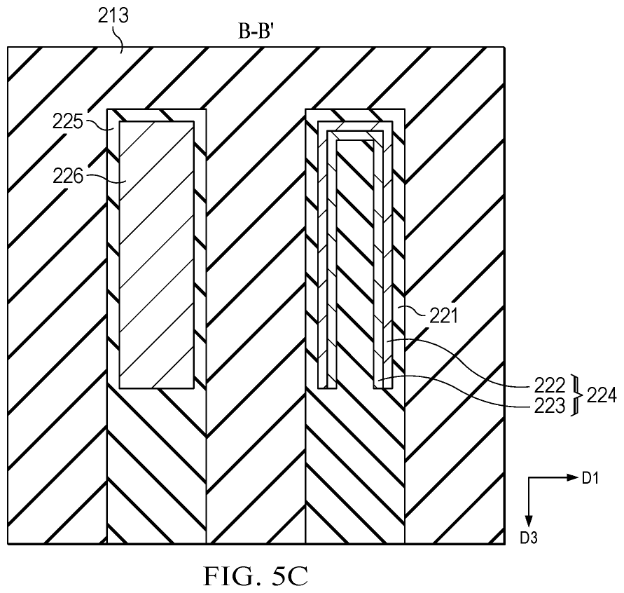

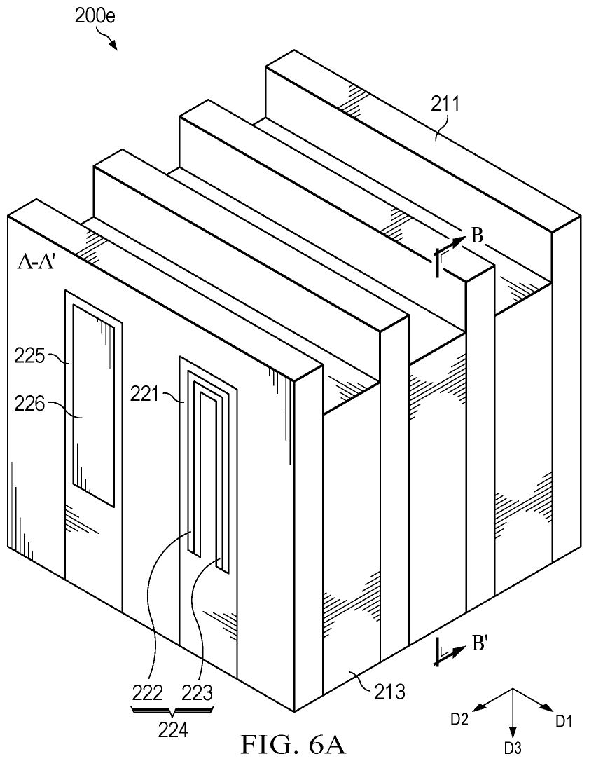

FIG. 5A shows an intermediate structure 200d of the semiconductor device after performing the removal of part of the semiconductor layer in operation S140. FIG. 5B is a plan view of the intermediate structure 200d as shown in FIG. 5A on an A-A′ plane. FIG. 5C is a cross-section view of the intermediate structure 200d as shown in FIG. 5A taken on a B-B′ plane.

As shown in FIGS. 4B to 5C, a part of the semiconductor layer 211 may be removed from the second side using a chemical mechanical polishing (CMP) process. For example, the insulation layer 213 may serve as a stop layer for removing part of the semiconductor layer 211, such that the semiconductor layer 211 after removal and the insulation layer 213 have a flat surface on the second side.

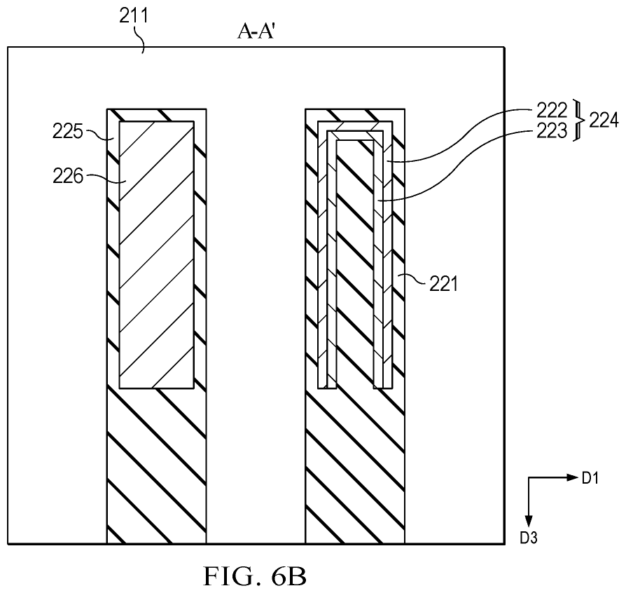

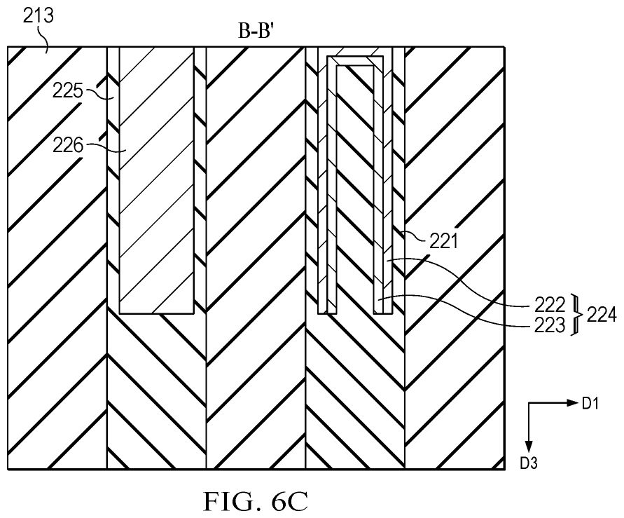

FIG. 6A shows an intermediate structure 200e of the semiconductor device after performing removal of part of the insulation layer and part of the first gate insulation layer in operation S140. FIG. 6B is a plan view of the intermediate structure 200e as shown in FIG. 6A on an A-A′ plane. FIG. 6C is a cross-section view of the intermediate structure 200e as shown in FIG. 6A taken on a B-B′ plane.

As shown in FIGS. 5A to 6C, a part of the insulation layer 213 may be removed from the second side using, for example, a dry etching process, and a part of the first gate insulation layer 221 may be further removed, to expose the first gate conductive layer 224. For example, in the case that the first gate conductive layer 224 comprises the gate blocking layer 222 and the gate metal layer 223, the gate blocking layer 222 may be exposed after removing part of the first gate insulation layer 221.

In some implementations, the second gate insulation layer 225 may be exposed after removing a part of the insulation layer 213. Further, the conductive layer 226 may be exposed after removing a part of the second gate insulation layer 225. For example, in the case that the materials of the conductive layer 226 and the first gate blocking layer 222 are the same (e.g., titanium nitride), part of the first gate insulation layer 221 and part of the second gate insulation layer 225 may be removed in the same process, thereby being favorable to improve the manufacturing efficiency and reduce the control difficulty of the etching process.

Operation S150 includes removing a part of the first gate conductive layer from the second side to divide the first gate conductive layer into first gates located on the opposite sidewalls of the second trenches, respectively.

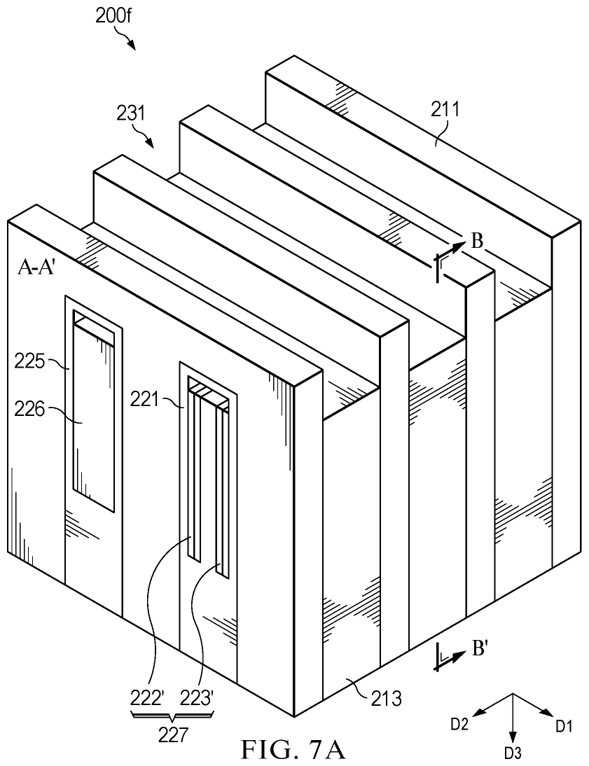

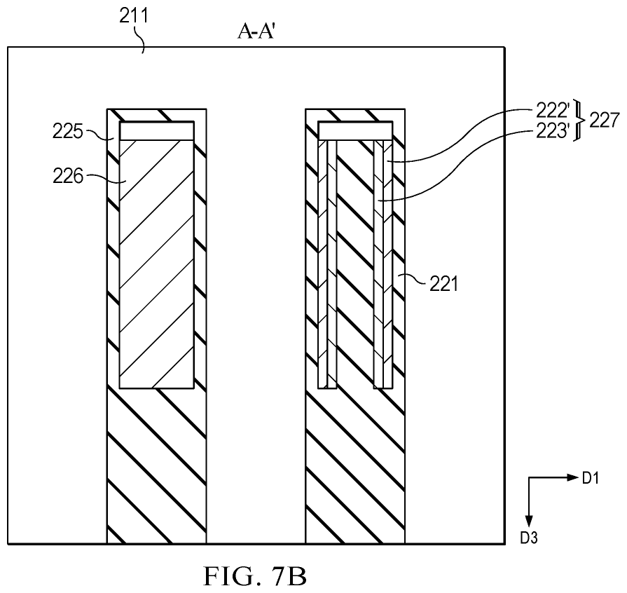

FIG. 7A shows an intermediate structure 200f of the semiconductor device after performing operation S150. FIG. 7B is a plan view of the intermediate structure 200f as shown in FIG. 7A on an A-A′ plane. FIG. 7C is a cross-section view of the intermediate structure 200f as shown in FIG. 7A taken on a B-B′ plane.

As shown in FIGS. 6A to 7C, a part of the first gate conductive layer 224 may be removed from the second side using, for example, a wet etching process. For example, the removed part of the first gate conductive layer 224 may be the part located at the bottoms of the second trenches 214 (referring to FIG. 3). Thus, the first gate conductive layer 224 is divided into two first gates 227 located on the opposite sidewalls of the second trenches 214 (referring to FIG. 3), respectively. For example, in the case that the first gate conductive layer 224 comprises the gate blocking layer 222 and the gate metal layer 223, part of the gate blocking layer 222 and part of the gate metal layer 223 at the bottoms of the second trenches 214 (referring to FIG. 3) may be removed. The removed part of the first gate conductive layer 224 extends in the second direction D2, such that the two first gates 227 after division are insulated from each other. One of the two first gates 227 extends continuously in the second direction D2 and serves as a word line of a DRAM.

In some implementations, the conductive layer 226 is exposed after performing operation S140. A part of the conductive layer 226 may be removed from the second side using, for example, a wet etching process, and the exposed surface of the conductive layer 226 after removal is substantially flush with the exposed surface (i.e., the surfaces of the first gates 227 close to the second side) of the first gate conductive layer 224 after removal, such that the parts of the first gates 227 and the conductive layer 226 close to the second side in the third direction D3 are relatively symmetrical, thereby being favorable to improve the control performance. Due to the limitation of the process, the error range of the exposed surface of the conductive layer 226 and the exposed surface of the first gate conductive layer 224 relative to the same reference plane may be between −10% and 10%. In examples, the removed part of the conductive layer 226 extends continuously in the second direction D2.

In some implementations, based on the material selection of the first gate conductive layer 224 and the conductive layer 226, in the process of removing a part of the first gate conductive layer 224, a part of the conductive layer 226 may be removed in the same etching process, such that the exposed surface of the conductive layer 226 is substantially flush with the surfaces of the first gates 227.

FIGS. 6A to 7C show the removed parts of the first gate conductive layer 224 and the conductive layer 226. In some other implementations, a part of the first gate conductive layer 224 on the opposite sidewalls of the second trenches 214 (referring to FIG. 3) and close to the second side may also be removed, to which the present application does not impose limitations.

After performing operation S150, as shown in FIGS. 7A to 7C, the intermediate structure 200f forms cavities 231 on the second side. The cavities 231 may comprise space surrounded by the first gate insulation layer 221 and the first gates 227, and space surrounded by the second gate insulation layer 225 and the conductive layer 226.

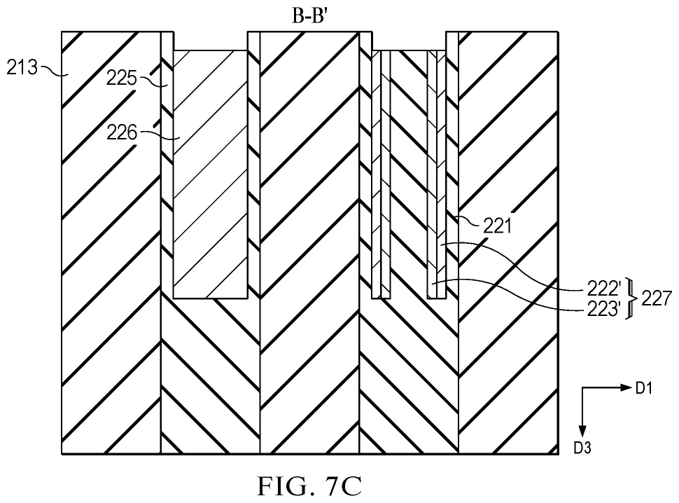

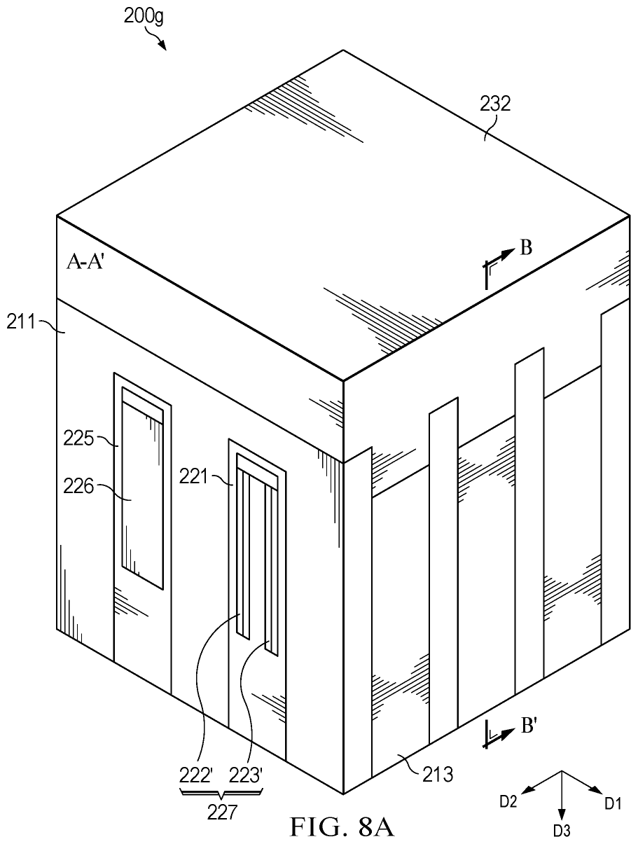

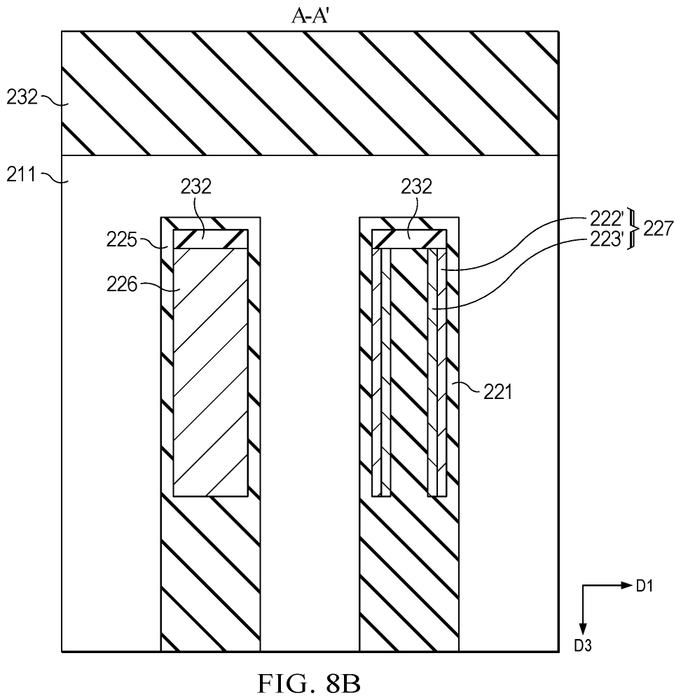

FIGS. 8A to 8C show an intermediate structure 200g after forming an insulation structure. FIG. 8B is a plan view of the intermediate structure 200g as shown in FIG. 8A on an A-A′ plane.

FIG. 8C is a cross-section view of the intermediate structure 200g as shown in FIG. 8A taken on a B-B′ plane.

In some implementations, as shown in FIGS. 8A to 8C, the manufacturing method 100 further comprises an operation of forming an insulation structure 232. In examples, the insulation structure 232 covering the semiconductor layer 211 may be formed on the second side using any suitable thin film deposition process, such as PVD, CVD, ALD, etc. For example, the insulation structure 232 may fill at least part of the cavities 231, and further extend and cover the surface of the semiconductor layer 211. For example, the insulation structure 232 may not be filled in the space surrounded by the first gate insulation layer 221 and the first gates 227, and/or the space surrounded by the second gate insulation layer 225 and the conductive layer 226, to which the present application does not impose limitations.

FIGS. 9A to 9C show a semiconductor device 200h. FIG. 9B is a plan view of the semiconductor device 200h as shown in FIG. 9A on an A-A′ plane. FIG. 9C is a cross-section view of the semiconductor device 200h as shown in FIG. 9A taken on a B-B′ plane.

In some implementations, a part of the insulation structure 232 may be removed from the second side using a chemical mechanical polishing (CMP) process to expose the semiconductor layer 211 again, so that the semiconductor layer 211 and the insulation structure 232 have a flat surface on the second side.

In some related arts, as shown in FIG. 3, after forming the second trenches 214, it is difficult to form flat surfaces at the bottoms of the second trenches 214 due to the limitation of the etching process. Thus, there is a need to fill (e.g., by an FCVD process) the second trenches 214 from the first side and performing multiple back-etchings to construct the flat surfaces at the bottoms of the second trenches 214. Then, the first gate insulation layer and the first gate conductive layer are sequentially formed on the sidewalls and the flat surfaces of the second trenches 214 on the first side. Subsequently, part of the first gate conductive layer at the bottoms of the second trenches is removed from the first side using punch etch to divide the first gate conductive layer into two first gates on the opposite sidewalls of the second trenches. However, in the above-mentioned related arts, in the operation of performing filling and multiple back-etchings on the second trenches 214 on the first side, the process cost is high, and the control is difficult. In addition, in the operation of removing part of the first gate conductive layer at the bottoms of the second trenches from the first side using punch etch, the process window is small, and it is difficult to completely divide the first gate conductive layer at the bottoms of the second trenches, which may cause electrical connection of the two first gates, thus influencing the electrical performance of the final product.

According to the manufacturing method of the semiconductor device provided by the above-mentioned implementations, the first gate insulation layer and the first gate conductive layer are directly formed on the inner walls of the second trenches, and part of the semiconductor layer, part of the first gate insulation layer and a part of the first gate conductive layer are removed from the second side of the semiconductor layer. The first gate conductive layer is then divided into the first gates located on the opposite sidewalls of the second trenches, respectively. As compared with the above-mentioned related arts, the operation of performing the filling and multiple back-etchings on the second trenches from the first side may be omitted, thereby being favorable to mitigate process costs and optimize the process window. The first gates located on the opposite sidewalls of the second trenches are formed on the second side, thereby being favorable to reduce process difficulty and improve the adaptability of technical evolution.

Some implementations of the present application further provide a semiconductor device. As shown in FIGS. 9A to 9C, the semiconductor device 200h comprises a plurality of semiconductor pillars 241, a first gate insulation layer 221 and first gates 227.

The plurality of semiconductor pillars 241 are arranged in an array along a first direction D1 and a second direction D2, and first ends of the plurality of semiconductor pillars 241 arranged along the first direction DI are connected with each other through, for example, a semiconductor layer 211. For example, the plurality of semiconductor pillars 241 connected with each other in the first direction D1 may be connected to the same bit line. Each of the semiconductor pillars 241 extends in a third direction D3. For example, the semiconductor pillar 241 serves as a channel of a transistor, and two ends of the semiconductor pillar 241 may be a source and a drain of the transistor.

The first gate insulation layer 221 is located on first sidewalls of the semiconductor pillars 241 and extends along the second direction D2. The first gates 227 are located on the surface of the first gate insulation layer 221 and extend along the second direction D2. The semiconductor pillar 241, the first gate insulation layer 221 and the first gate 227 may constitute a transistor of one memory cell in DRAM. The first gates 227 continuously extending in the second direction D2 may be used to control a plurality of transistors arranged in the second direction D2 synchronously, and can serve as word lines of DRAM. The surfaces of a plurality of the first gates 227 close to the first ends are substantially flush. An error range of the surfaces of the plurality of first gates 227 close to the first ends relative to the same reference plane may be between −10% and 10%. For example, the thicknesses of the first gates 227 in the first direction D1 are consistent along the third direction D3. For another example, the cross-section shapes of the first gates 227 on a plane perpendicular to the second direction D2 are rectangular.

According to the semiconductor device provided by the above-mentioned implementations, since the surfaces of the plurality of first gates close to the first ends are substantially flush, the structural consistency of the first gates in the semiconductor device can be improved, thereby being favorable to improve the influence on the performance of the semiconductor device due to structural differences.

In some implementations, the first gates 227 may comprise a gate blocking layer 222′ and a gate metal layer 223′. The gate blocking layer 222′ is located on the surface of the first gate insulation layer 221, and the gate metal layer 223′ is located on the surface of the gate blocking layer 222′. In other words, the gate blocking layer 222′ is located between the surface of the first gate insulation layer 221 and the gate metal layer 223′. The gate blocking layer 222′ may be used to block diffusion of metal materials and also used to improve mutual attachment between the first gate insulation layer 221 and the gate metal layer 223′. For example, the material of the gate blocking layer 222′ may include titanium nitride, and the material of the gate metal layer 223′ may include tungsten.

In some implementations, the semiconductor device 200h may further comprise a second gate insulation layer 225 and a conductive layer 226. The second gate insulation layer 225 may be located on second sidewalls of the semiconductor pillars 241 and extend along the second direction D2. The first sidewalls and the second sidewalls are opposite sidewalls in the first direction D1. The conductive layer 226 may be located on the surface of the second gate insulation layer 225 and extend along the second direction D2. For example, the second gate insulation layer, the conductive layer and the second gate insulation layer may be sequentially disposed between the sidewalls of the two semiconductor pillars that are adjacent in the first direction D1. The conductive layer 226 extending continuously in the second direction D2 and the first gates 227 may face each other relative to the semiconductor pillars 241, and the conductive layer 226 may serve as back gates. For example, the interference between adjacent word lines may be prevented by applying a reference voltage (e.g., a ground voltage) to the back gates. Optionally, the material of the conductive layer 226 may include titanium nitride.

In some implementations, the conductive layer 226 may be all replaced by the second gate insulation layer (not shown), and the second gate insulation layer may have air gaps at the center part. The second gate insulation layer with the air gaps can improve the insulation performance, thereby preventing the interference between adjacent word lines. In some other implementations, similar to the first gates 227, the semiconductor device 200h may comprise second gates (not shown) which are located on the surface of the second gate insulation layer 225 and extend along the second direction D2. The second insulating material layer is located on the surfaces of the second gates. In other words, the second gate insulation layer, the second gate, the second insulating material layer, the second gate and the second gate insulation layer are sequentially disposed between the sidewalls of the two semiconductor pillars that are adjacent in the first direction D1. As compared with the conductive layer 226 as shown in FIGS. 9A to 9C, the two second gates may separately control the transistors located on two sides thereof, thereby being favorable to improve the control flexibility of the back gates.

In some implementations, the sizes of the first gates 227 in the third direction D3 are the same as the size of the conductive layer 226 in the third direction D3. For example, the surfaces of the first gates 227 and the conductive layer 226 close to the second ends are substantially flush. The sizes of the first gates 227 and the conductive layer 226 in the third direction D3 are the same, which can make both of them relatively symmetrical in the third direction D3, thereby being favorable to improve the control performance.

Some implementations of the present application further provide a memory system. The memory system comprises the semiconductor device (e.g., the semiconductor device 200h) as described in any implementation above, and a memory controller.

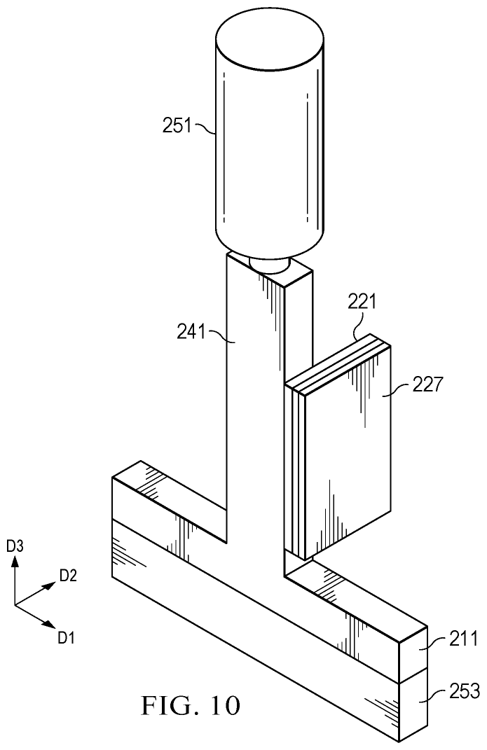

In some implementations, the semiconductor device 200h may serve as a part of DRAM. FIG. 10 is a schematic diagram of a memory cell of example implementations of the present application. In this implementation, as shown in FIGS. 9A to 9C and 10, one semiconductor pillar 241, and a first gate insulation layer 221 and a first gate 227 located on a first sidewall of the semiconductor pillar 241, may constitute one transistor. A voltage is applied through the first gate 227 to control the turning-on of the transistor. A second end of one semiconductor pillar 241 may be coupled to a capacitor structure 251, i.e., one transistor and one capacitor structure may constitute one dynamic random memory cell. A plurality of memory cells are arranged in an array in a first direction D1 and a second direction D2 to constitute a memory cell array. The first ends of a plurality of the semiconductor pillars 241 arranged in the first direction D1 are connected with each other, and connected to the same bit line 253. The memory controller may be used to control various memory cells in the memory cell array to achieve storage and reading of data.

In some implementations, the memory system may serve as a memory or buffer in an electronic apparatus. In some other implementations, the memory system may be for auxiliary use in a solid-state drive, which can make improvements on the solid-state drive, such as reading and writing. Current high-end solid-state drive products mostly select embedded dynamic random memories to improve the performance of the products, and improve the random reading-writing speeds. Exemplarily, when writing files, especially writing small files, small files are stored in a Flash after being processed by the dynamic random memories, such that the solid-state drive has higher storage efficiency and faster speed.

The above descriptions are merely the descriptions of implementations of the present application and technical principles used. Those skilled in the art should understand that, the protection scope of the present application is not limited to the technical solutions formed by specific combinations of the above technical features, and meanwhile, should also encompass other technical solutions formed by any combinations of the above technical features or equivalent features thereof, for example, technical solutions formed by interchanging the above-mentioned features with the technical features having similar functions as disclosed (but not limited to those) in the present application, without departing from the technical concept.

What is claimed is:

1. A manufacturing method of a semiconductor device, comprising:
forming first trenches extending along a first direction on a first side of a semiconductor layer, and forming an insulation layer within the first trenches;
forming second trenches extending along a second direction on the first side, depths of the second trenches being less than depths of the first trenches, wherein the first direction intersects the second direction;
forming a first gate insulation layer and a first gate conductive layer sequentially on inner walls of the second trenches;
removing part of the semiconductor layer, part of the insulation layer and part of the first gate insulation layer from a second side of the semiconductor layer facing away from the first side, to expose the first gate conductive layer; and
removing a part of the first gate conductive layer from the second side, to divide the first gate conductive layer into first gates located on opposite sidewalls of the second trenches respectively.

2. The manufacturing method of claim 1, wherein the method further comprises:
forming third trenches extending along the second direction on the first side, the third trenches and the second trenches being arranged alternately in the first direction; and
forming a second gate insulation layer within the third trenches.

3. The manufacturing method of claim 2, wherein forming the second gate insulation layer within the third trenches comprises:
forming a second gate insulation layer on inner walls of the third trenches; and
forming a conductive layer within space surrounded by the second gate insulation layer.

4. The manufacturing method of claim 3, wherein the method further comprises:
removing a part of the conductive layer from the second side, such that an exposed surface of the conductive layer is substantially flush with an exposed surface of the first gate conductive layer.

5. The manufacturing method of claim 3, wherein in a process of removing a part of the first gate conductive layer, a part of the conductive layer is removed in the same process, such that an exposed surface of the conductive layer is substantially flush with an exposed surface of the first gate conductive layer.

6. The manufacturing method of claim 5, wherein a material of the conductive layer includes titanium nitride.

7. The manufacturing method of claim 3, wherein the method further comprises:
removing a part of the first gate conductive layer and a part of the conductive layer from the first side, such that an exposed surface of the first gate conductive layer is substantially flush with an exposed surface of the conductive layer; and
filling an insulating material within space of the second trenches and the third trenches.

8. The manufacturing method of claim 1, wherein the first gate conductive layer comprises a gate blocking layer and a gate metal layer, and
wherein forming the first gate insulation layer and the first gate conductive layer sequentially on the inner walls of the second trenches comprises:
forming the first gate insulation layer, the gate blocking layer and the gate metal layer sequentially on the inner walls of the second trenches.

9. The manufacturing method of claim 8, wherein a material of the gate blocking layer includes titanium nitride, and a material of the gate metal layer includes tungsten.

10. The manufacturing method of claim 1, wherein after removing a part of the first gate conductive layer from the second side to divide the first gate conductive layer into the first gates located on the opposite sidewalls of the second trenches respectively, the method further comprises:
forming an insulation structure covering the semiconductor layer on the second side.

11. A semiconductor device, comprising:
a plurality of semiconductor pillars arranged in an array along a first direction and a second direction, first ends of the plurality of semiconductor pillars arranged along the first direction being connected with each other;
a first gate insulation layer located on first sidewalls of the semiconductor pillars and extending along the second direction; and
first gates located on a surface of the first gate insulation layer and extending along the second direction,
wherein surfaces of a plurality of the first gates close to the first ends are substantially flush, the first direction, the second direction and a third direction intersect each other, and the third direction is an extending direction of each of the semiconductor pillars.

12. The semiconductor device of claim 11, wherein thicknesses of the first gates in the first direction are consistent along the third direction.

13. The semiconductor device of claim 11, wherein cross-section shapes of the first gates on a plane perpendicular to the second direction are rectangular.

14. The semiconductor device of claim 11, wherein the semiconductor device further comprises:
a second gate insulation layer located on second sidewalls of the semiconductor pillars and extending along the second direction, the first sidewalls and the second sidewalls being opposite sidewalls in the first direction; and
a conductive layer located on a surface of the second gate insulation layer and extending along the second direction.

15. The semiconductor device of claim 14, wherein the second gate insulation layer, the conductive layer and the second gate insulation layer are sequentially disposed along the first direction between adjacent ones of the semiconductor pillars in the first direction.

16. The semiconductor device of claim 14, wherein a material of the conductive layer includes titanium nitride.

17. The semiconductor device of claim 11, wherein the first gates comprise a gate blocking layer and a gate metal layer, the gate blocking layer being located between the surface of the first gate insulation layer and the gate metal layer.

18. The semiconductor device of claim 17, wherein a material of the gate blocking layer includes titanium nitride, and a material of the gate metal layer includes tungsten.

19. The semiconductor device of claim 14, wherein sizes of the first gates in the third direction are the same as a size of the conductive layer in the third direction.

20. A memory system, comprising:
a semiconductor device, comprising:
a plurality of semiconductor pillars arranged in an array along a first direction and a second direction, first ends of the plurality of semiconductor pillars arranged along the first direction being connected with each other;
a first gate insulation layer located on first sidewalls of the semiconductor pillars and extending along the second direction; and
first gates located on a surface of the first gate insulation layer and extending along the second direction,
wherein surfaces of a plurality of the first gates close to the first ends are substantially flush, the first direction, the second direction and a third direction intersect each other, and the third direction is an extending direction of each of the semiconductor pillars; and
a memory controller coupled to the semiconductor device and configured to control the semiconductor device.
